(19) United States
(12) Patent Application Publication
(10) Pub. No.: US 2022/0246778 A1
(43) Pub. Date: Aug. 4, 2022

(54) SOLAR MODULE WITH METAL FOIL INTERCONNECTION OF BACK-CONTACTED PHOTOVOLTAIC CELLS

(71) Applicants: Kathryn FISHER, Scottsdale, AZ (US); Zachary HOLMAN, Phoenix, AZ (US); Charles GAY, Westlake Village, CA (US); David LEVY, Rochester, NY (US)

(72) Inventors: Kathryn FISHER, Scottsdale, AZ (US); Zachary HOLMAN, Phoenix, AZ (US); Charles GAY, Westlake Village, CA (US); David LEVY, Rochester, NY (US)

(21) Appl. No.: 17/619,210

(22) PCT Filed: Jun. 12, 2020
(86) PCT No.: PCT/US2020/037627

§ 371 Date: Dec. 14, 2021

Related U.S. Application Data
(60) Provisional application No. 62/861,973, filed on Jun. 14, 2019.

(51) Int. Cl. H01L 31/05; H01L 31/048; H01L 31/18

(52) U.S. Cl. CPC H01L 31/0516; H01L 31/18; H01L 31/048

(57) ABSTRACT

A photovoltaic module includes a metal foil defining a multiplicity of electrical contacts, each electrical contact electrically isolated from the other electrical contacts, and a plurality of back-contact photovoltaic cells superimposed over the metal foil and electrically connected via the multiplicity of electrical contacts. Each photovoltaic cell includes a first side configured to absorb light and a second side including a first electrically conductive protrusion and a second electrically conductive protrusion. The first electrically conductive protrusion of a first one of the photovoltaic cells is in direct electrical communication with a first one of the multiplicity of electrical contacts, and the second electrically conductive protrusion of the first one of the photovoltaic cells is in direct electrical communication with a second one of the electrical contacts.

### CROSS-REFERENCE TO RELATED APPLICATION

This application claims the benefit of U.S. Patent Application No. 62/861,973 filed on Jun. 14, 2019, which is incorporated by reference herein in its entirety.

### STATEMENT OF GOVERNMENT INTEREST

This invention was made with government support under DE-EE0007538 awarded by the Department of Energy. The government has certain rights in the invention.

### TECHNICAL FIELD

This invention relates to a photovoltaic module incorporating back-contact photovoltaic cells, metal foil electrical contacts, and a method for connecting the electrical contacts to the cells, and particularly relates to the architecture (materials and layer order) and method of manufacture (fabrication method and procedure) of the photovoltaic module.

### BACKGROUND

Photovoltaic cells within a photovoltaic module typically use metal, for example in the form of fingers and busbars, to collect and transport photogenerated charge carriers with minimal resistive losses. However, metal on the front, or sunward, side of photovoltaic cells decreases efficiency of the cells by reflecting incoming light. Back-contact photovoltaic cells, with most or all of their metal on their rear (ground-facing) side, can include not only those cells that have negative- and positive-polarity semiconductor regions on the rear sides, but also those that have one or the other polarity region at the front side, with the metal contacting this region wrapping through vias in the cell to reach the rear side.

There are several architectures and methods by which back-contact photovoltaic cells are interconnected to form serial and parallel electrical connections between adjacent cells in a module. In one example, metal tabbing ribbon may be soldered to busbars on the photovoltaic cells that may, for example, extend across a length of the photovoltaic cells. In another example, the metal on the rear of each photovoltaic cell is made sufficiently thick to conduct current across the width of the solar cell with minimal resistive losses, and soldering of metal tabbing ribbons need only occur at the edges of cell. In yet another example, a metal foil is attached to the photovoltaic cells with an electrically conductive adhesive. However, these architectures have disadvantages that increase cost and decrease efficiency, reliability, and energy yield.

### SUMMARY

This disclosure pertains to the design and fabrication of photovoltaic modules having back-contact photovoltaic cells, including an arrangement of materials and a method of making the arrangement that result in an inexpensive, high-efficiency, and reliable photovoltaic module.

Photovoltaic modules described herein include a metal foil that transports current with minimal resistance. This metal foil obviates the need for soldered tabbing ribbons or thick metallization on the photovoltaic cells, both of which have been used in back-contact photovoltaic modules to perform the same current-transport function. The metal foil interconnects adjacent photovoltaic cells to form serial and parallel electrical connections. The foil may be separated into segments so that only selected photovoltaic cells are interconnected, the others being electrically isolated by the openings between portions of the foil. The metal foil makes low-resistance contact to metal regions on the photovoltaic cells, facilitated by laser welds, a thin adhesive (without metal particle or flakes), or some combination thereof. Attachment by laser welding or a thin adhesive contributes to high-efficiency and reliable modules with metal foil.

Photovoltaic module architecture described herein facilitates laser welding or attachment with a thin adhesive, both of which require that regions of the metal foil be proximate to or in direct contact with the metal regions on the photovoltaic cells. In particular, embossing may cause the regions of the metal foil that contact the photovoltaic cell to stand in relief with respect to the remainder of the foil. Embossing is of particular utility when an encapsulant layer, which may have a thickness between 10 μm and 800 μm, is between the metal foil and photovoltaic cell, as the encapsulant may have openings that allow passage of the embossed regions of the foil such that those regions of the foil make mechanical contact with the photovoltaic cell through the encapsulant layer. The embossing can thus obviate the need for an additional conductive material, such as electrically conductive adhesive, in the perforations of the encapsulant layer.

The methods described herein for fabrication of back-contact photovoltaic modules include stacking, or laying-up, the module materials and laminating the resulting stack. Some implementations include embossing of the metal foil, application of a thin adhesive during lay-up prior to the placement of the photovoltaic cells in the module stack, and laser welding of the foil to the cells after module lamination.

In a first general aspect, a photovoltaic module includes a metal foil defining a multiplicity of electrical contacts, each electrical contact electrically isolated from the other electrical contacts, and a plurality of back-contact photovoltaic cells superimposed over the metal foil and electrically connected via the multiplicity of electrical contacts. Each photovoltaic cell includes a first side configured to absorb light and a second side including a first electrically conductive protrusion and a second electrically conductive protrusion. The first electrically conductive protrusion of a first one of the photovoltaic cells is in direct electrical communication with a first one of the multiplicity of electrical contacts, and the second electrically conductive protrusion of the first one of the photovoltaic cells is in direct electrical communication with a second one of the electrical contacts.

Implementations of the first general aspect include one or more of the following features.

The multiplicity of electrical contacts includes pairs of adjacent electrical contacts, each pair of adjacent electrical contacts separated by an opening through the metal foil. In some cases, the first electrically conductive protrusion of the first one of the photovoltaic cells is laser welded to the first one of the multiplicity of electrical contacts. In some cases, the first electrically conductive protrusion of the first one of the photovoltaic cells is adhered to the first one of the multiplicity of electrical contacts with a non-electrically conductive adhesive.

In some cases, the metal foil is a metal foil layer. Each of the multiplicity of electrical contacts is embossed such that an embossed portion of each of the multiplicity of electrical contacts extends from a plane of the metal foil toward the plurality of photovoltaic cells. Each embossed portion typically extends from the plane of the metal foil by a distance between 10 μm and 800 μm. The first electrically conductive protrusion of a first one of the photovoltaic cells is in direct electrical communication with the embossed portion of the first one of the multiplicity of electrical contacts, and the second electrically conductive protrusion of the first one of the photovoltaic cells is in direct electrical communication with the embossed portion of the second one of the electrical contacts.

In some cases, an encapsulant layer is positioned between the metal foil and the plurality of photovoltaic cells. Each of the multiplicity of electrical contacts is embossed such that an embossed portion of each of the multiplicity of electrical contacts extends from a plane of the metal foil and through an opening in the encapsulant layer toward the plurality of photovoltaic cells. A thickness of the encapsulant layer and the distance each embossed portion extends from the plane of the metal foil are substantially the same.

The photovoltaic module may include a first outer layer and a second outer layer, wherein the metal foil and the plurality of photovoltaic cells are positioned between the first outer layer and the second outer layer. The photovoltaic module may include a first encapsulant layer between the first outer layer and the plurality of photovoltaic cells and a second encapsulant layer between the metal foil and the second outer layer.

In a second general aspect, fabricating a photovoltaic module includes separating a metal foil into plurality of electrically isolated electrical contacts, superimposing a plurality of photovoltaic cells over the plurality of electrical contacts, each photovoltaic cell comprising a first electrically conductive protrusion and a second electrically conductive protrusion, and forming a direct electrical coupling between the first electrically conductive protrusion of a first one of the photovoltaic cells and a first one of the electrical contacts and between the second electrically conductive protrusion of the first one of the photovoltaic cells and a second one of the electrical contacts.

Implementations of the second general aspect may include one or more of following features.

Separating the metal foil may include removing a portion of the metal foil (e.g., forming an opening, such as elongated opening, in the metal foil). Removing the portion of the metal foil includes laser ablating or mechanically milling the portion of the metal foil. The metal foil may be embossed before separating the metal foil into the plurality of electrical contacts. Embossing the metal foil yields an embossed portion of the each of the multiplicity of electrical contacts extending from a plane of the metal foil.

The second general aspect may further include forming openings in an intermediate layer (e.g., encapsulant layer) before embossing the metal foil, superimposing the metal foil and the intermediate layer, and embossing the metal foil through the openings in the intermediate layer. In some cases, the first electrically conductive protrusion of the first one of the photovoltaic cells is laser welded to the first one of the electrical contacts. Forming the direct electrical coupling between the first electrically conductive protrusion of the first one of the photovoltaic cells and the first one of the electrical contacts may include adhering the first electrically conductive protrusion of the first one of the photovoltaic cells and the first one of the electrical contacts with an non-electrically conductive adhesive.

Photovoltaic modules described herein with a plurality of back-contact photovoltaic cells can be interconnected with an inexpensive metal foil, such as aluminum. As the spacing of electrical connection points between the photovoltaic cells and the metal foil decreases, the amount of metal on the photovoltaic cells required to provide a maximum resistance for charge-carrier transport decreases, and the current is carried in the foil instead of the metal on the photovoltaic cell. The metal applied directly to the photovoltaic cells is typically more expensive than the metal used as the metal foil, allowing a cost reduction for the disclosed photovoltaic modules. It is a further advantage to provide a low-resistance electrical interconnection between a plurality of back-contact photovoltaic cells and metal foil with laser welding or thin adhesive through which electrical conduction occurs.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1 is a cross-sectional view of a portion of a photovoltaic module.

FIG. 2 is a cross-sectional view of a portion of a photovoltaic module.

FIG. 3 is a cross-sectional view of a portion of a photovoltaic module.

FIG. 4 is an exploded view of a portion of photovoltaic module.

FIG. 5 is an exploded, cut-away view of a portion of a photovoltaic module.

FIG. 6 is an exploded, cut-away view of a portion of a photovoltaic module.

FIG. 7 is a top view of a metal foil having a first arrangement of openings and embossed portions.

FIG. 8 is a top view of the metal foil of FIG. 7 aligned with and connected to photovoltaic cells.

FIG. 9 is a top view of a photovoltaic cell of FIG. 8.

FIG. 10 is a top view of a metal foil having a second arrangement of openings and embossed portions.

FIG. 11 is a top view of the metal foil of FIG. 10 aligned with and connected to photovoltaic cells.

FIG. 12 is a top view of the photovoltaic cell of FIG. 11.

FIG. 13 depicts operations in a fabrication sequence for a photovoltaic module.

FIG. 14 shows current density-voltage characteristics of a photovoltaic module.

FIG. 15 shows the relative performance of a photovoltaic module as a function of hours of damp-heat exposure.

FIG. 16 shows the relative performance of a photovoltaic module as a function of numbers of thermocycles.

FIG. 17 shows the relative performance of a photovoltaic module as a function of numbers of humidity-freeze cycles.

### DETAILED DESCRIPTION

This disclosure relates to a photovoltaic module including, from its first (front or sunward side) to its second (back or ground-facing side), a first outer layer, a first encapsulant, a plurality of back-contact photovoltaic cells, an intermediate layer, a metal foil separated into multiple electrically isolated electrical contact, a second encapsulant, and a second outer layer. Each of these layers or elements may be freestanding prior to lamination and may be combined altogether or in intermediate sections to form a cohesive module or laminate.

The first outer layer is formed of an optically transparent material, such as a glass or plastic, that withstands hail and wind-loading tests stipulated in solar module product qualification tests (e.g., IEC61215) when used in conjunction with other layers in the module. One example of a suitable glass is heat-tempered, low-Fe, soda-lime glass, or. A thickness of the first outer layer is typically in a range of 1 mm to 5 mm or 2 mm to 4 mm (e.g., 3 mm). The first outer layer may have an anti-reflection coating. In one example, the anti-reflection coating includes silica particles deposited by a sol-gel or vacuum deposition process.

The first (or front) encapsulant typically includes one or more layers such as an ethylene-vinyl acetate (EVA) layer, a polyolefin (POE) layer, or both. Other suitable materials for the first enapsulant include materials capable of forming an optically transparent layer with refractive index of approximately 1.5 during a lamination cycle (application of heat and pressure). The first encapsulant may be between 10 μm and 800 μm thick and exhibit sufficient adhesion to the first outer layer and the photovoltaic cells to resist delamination after the ultraviolet (UV), thermal, and moisture tests stipulated in solar module product qualification tests (e.g., IEC61215).

The back-contact photovoltaic cells have positive and negative regions in the semiconductor that terminate in metal regions (cell metallizations, or electrically conductive protrusions) on a second surface (the rear or back-facing side) of the cells. Cell metallization may include screen printed, vacuum deposited, or plated metal, such as silver, aluminum, or copper. The positive and negative metallized regions may be distributed in a pattern on the second surface of the cell. Examples of suitable patterns include arrays of dots, interdigitated lines, and radial spokes. A dielectric layer may be applied (for example, by screen printing) in patterns over the positive and negative metallized regions, enabling groups of these regions to be connected together, either by a second layer of screen printed or vacuum deposited metal, by a metal foil, or a combination thereof.

The intermediate layer typically includes one or more polymer materials situated between the second side (or back) of a photovoltaic cell and the metal foil. The intermediate layer may be a continuous or discontinuous layer. A first example of a suitable intermediate layer includes one or more layers of encapsulant or adhesive, such as ethylene-vinyl acetate (EVA) or polyolefin (POE) (e.g., between 10 μm-800 μm thick). A second example of a suitable intermediate layer includes a tri-layer encapsulant stack (e.g., 10 μm-100 μm) of a solid polymer sheet such as polyethylene terephthalate (PET), polyvinylidine fluoride (PVDF), or polytetrafluoroethylene (PTFE) that does not melt at lamination temperatures sandwiched between two encapsulant layers (e.g., each 10 μm-100 μm in thickness). A third example of a suitable intermediate layer includes a layer of a polymeric material (e.g., 1 μm-50 μm thick) that is a liquid at room temperature and cures at lamination temperatures (e.g., 130° C.-160° C.) that is applied either to the cell or the foil electrical contact by screen printing, jet dispensing, blade coating, or the like.

The intermediate layer may be patterned. In one example, a suitable pattern includes perforations or openings in the regions where electrical communication or direct contact is to be made between the electrically conductive protrusions from a photovoltaic cell (e.g., metallizations, fingers, busbars) and the metal foil. Patterning of the intermediate layer to form perforations or openings may be achieved using a laser, cutting die, or other subtractive process. In some cases, the intermediate layer includes openings through which the metal foil is electrically coupled with the electrically conductive protrusions of the photovoltataic cell during the lamination process.

The metal foil is separated in a multiplicity of electrical contacts. Each electrical contact is configured to be in direct electrical communication or coupling with electrically conductive protrusions of the back-contact photovoltaic cells in the photovoltaic module. As used herein, “direct electrical communication” or “direct electrical coupling” means that electric charge flows directly between electrically conductive protrusions of a photovoltaic cell and the metal foil in the absence of any intervening electrically conductive material (e.g., in the absence of an electrically conductive adhesive that includes metallic particles). A suitable thickness of the metal foil is typically in a range of 20 μm to 100 μm (e.g., 40 μm to 70 μm). Examples of suitable metals for the metal foil include copper, aluminum, or any combination thereof (e.g., aluminum coated with copper, copper or aluminum coated with an anti-oxidant or adhesion-promotion layer).

In some cases, the metal foil is embossed or otherwise deformed into a three-dimensional shape such that portions of the metal foil that are intended to contact the electrically conductive protrusions of the photovoltaic cells extend from (do not lie in the same plane(s) as) portions of the metal foil that are intended to be isolated from the metal regions on the photovoltaic cells. In particular, the embossed portions may protrude through perforations in the intermediate layer, such that the embossed portions of the metal foil are in direct electrical communication with (e.g., directly contact) the electrically conductive protrusions of the photovoltaic cells. The flat (unembossed) portions of the metal foil may be isolated from the photovoltaic cell by the intermediate layer. The embossed portions of the metal foil may have the same or a similar spatial pattern as some or all of the electrically conductive protrusions on the photovoltaic cells, or they may be of a different pattern. In other cases, the metal foil is flat (e.g., planar) and in direct electrical communication with the photovoltaic cell everywhere there is no dielectric isolation layer on the cell, particularly when used in conjunction with an intermediate layer that is a liquid at room temperature and cures during a lamination cycle.

Three-dimensional shaping of the metal foil may be achieved by several methods. A first method includes embossing a freestanding foil using a mandrel or single- or double-sided embossing die prior to attachment of the foil (by lamination or another means) to the intermediate layer or second encapsulant. A second method includes attaching a freestanding foil to the intermediate layer (by lamination or another means) prior to shaping, patterning the intermediate layer, and embossing the metal foil through the perforated regions of the intermediate layer using a mandrel or single- or double-sided embossing die. A third method includes patterning the intermediate layer, embossing a freestanding metal foil through the perforated regions of the intermediate layer using a mandrel or single-sided embossing die, and attaching the shaped metal foil to the patterned intermediate layer (by lamination or another means).

The embossed or flat (e.g., planar) metal foil may be separated into multiple electrical contacts at one of several stages in the module fabrication process. The separation achieves sufficient spacing between the electrical contacts so that they are electrically isolated from one another. In one example, a ribbon having a width of about 1 mm to about 5 mm is removed from the metal foil by laser ablation, mechanical milling, or another means, after the metal foil is attached to the intermediate layer, so that the electrically isolated electrical contacts of the coplanar foil, with a 1 mm to 5 mm opening between their edges, form the electrical contacts.

The separation may be performed such that the metal foil is separated into multiple electrical contacts having any desired shape, but preferred shapes facilitate the interconnection of the photovoltaic cells in the module. In particular, after the metal foil is connected to a photovoltaic cell, the separation of the metal foil provides a first electrical contact that electrically connects the negative polarity regions of the cell and is electrically isolated from the positive polarity regions of the cell, and a second electrical contact that electrically connects the positive polarity regions of the cell and is electrically isolated from the negative polarity regions of the cell. Additionally, to form a serial interconnection, separation of the foil may provide for the positive polarity regions of a photovoltaic cell being electrically connected to the negative polarity regions of the next cell in the string. The separation of electrical contacts of the metal foil provides electric isolation from other adjacent cells. The separation of the electrical contacts of the metal foil provides electrical isolation of adjacent strings, with string ends being oriented to enable connection to bypass diodes in a junction box.

The second (or rear) encapsulant typically includes one or more layers such as an EVA layer, a POE layer, or both. A thickness of the second encapsulant is typically in a range between 10 μm and 800 μm. The second encapsulant adheres to the metal foil and the second outer layer. The adhesion is sufficient to resist delamination after UV, thermal, and moisture tests stipulated in solar module product qualification tests (for example, IEC61215). The second outer layer can be optically transparent or optically opaque (e.g., white, black, or clear), depending at least in part on the foil-to-photovoltaic-cell interconnection method used. The second outer layer may define one or more openings. A junction box may be positioned proximate each of the one or more openings. Each junction box provides an electrical connection point between the electrical contacts of the metal foil, bypass diodes, and external leads in accordance with photovoltaic module interconnection codes. The transition between the external cables and the electrical contacts may be realized in a number of ways, such as soldering copper bussing wire to components inside the junction box at one end and connecting the other end to the end electrical contacts of the metal foil (e.g., by the same method used to connect the foil to the cells or by another method such as resistance welding).

The photovoltaic module may be assembled in a manner similar to that used to assemble other types of photovoltaic modules, in particular those with conductive backsheets or metal foil electrical contacts. The second outer layer, second encapsulant, metal foil, and intermediate may be stacked or applied as appropriate, their edges aligned. In accordance with the aforementioned methods by which the metal foil may be embossed and separated, the metal foil may already be attached to the second encapsulant and second outer layer, attached to the patterned intermediate layer, or a combination thereof. The photovoltaic cells may be placed on the intermediate layer in the appropriate positions for their interconnection, for example by a pick-and-place robot or another suitable means.

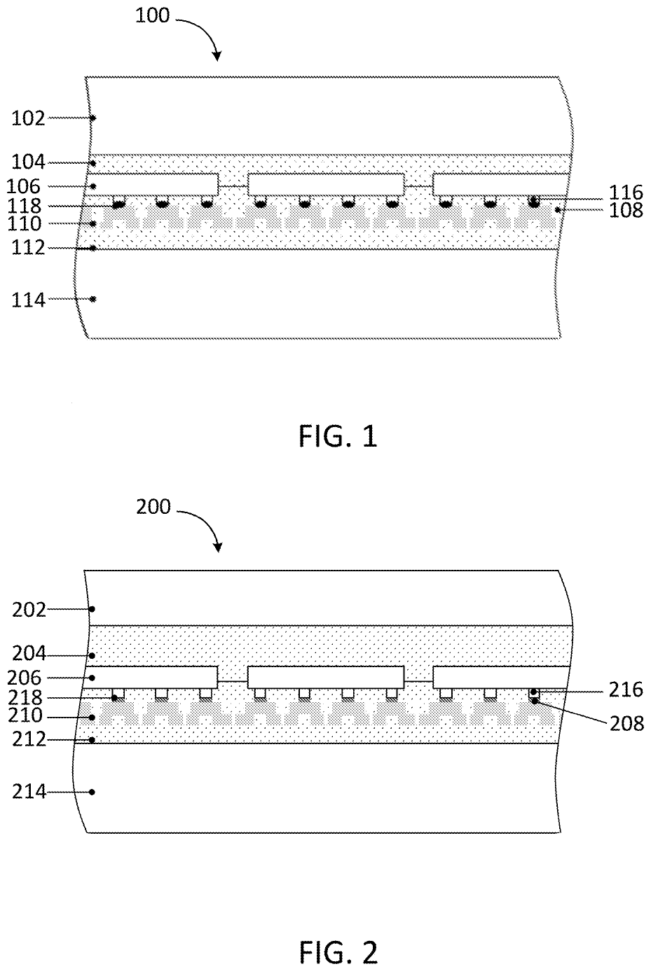

FIG. 1 is a cross-sectional view of photovoltaic module 100. Photovoltaic module 100 has first outer layer 102, first encapsulant 104, back-contact photovoltaic cells 106, intermediate layer 108, metal foil 110, second encapsulant 112, and second outer layer 114. Intermediate layer 108 is patterned and defines perforations. Metal foil 110 is embossed through the perforations in the intermediate layer. Second outer layer 114 is optically transparent.

Photovoltaic cells 106 can be positioned on intermediate layer 108, and the first encapsulant 104 and first outer layer 102 stacked on top of the photovoltaic cells. The stack of materials is heated and pressurized to form a laminate. Alternatively, any other suitable process may be used to remove air bubbles from photovoltaic module 100, melt, and cross-link or cure the encapsulant or adhesive layers, and bring the embossed areas of metal foil 110 into more intimate contact with the electrically conductive protrusions 116 of photovoltaic cells 106. Direct electrical communication between the metal foil 110 and electrically conductive protrusions 116 on photovoltaic cells 106 is achieved (e.g., after lamination) using a laser to weld the two metals together through second outer layer 114 of photovoltaic module 100, forming laser welds 118. The laser may have any wavelength that is not appreciably absorbed by second outer layer 114 and second encapsulant 112. Examples of suitable lasers include a millisecond Nd:YAG laser that can deliver 30 mJ-150 mJ per pulse, a fiber optic laser running at frequencies between 10 kHZ and 4 MHz, or any other laser that enables the metal of the foil electrical contact to alloy with the metal on the cell.

Photovoltaic module 100 may include an edge seal around at least one edge of the module, a frame attached around at least one edge of the module, mounting rails attached proximate the second outer layer of the module, a junction box attached to the second outer layer, or any combination thereof.

FIG. 2 is a cross-sectional view of photovoltaic module 200. Photovoltaic module 200 has first outer layer 202, first encapsulant 204, photovoltaic cells 206, intermediate layer 208, metal foil 210, second encapsulant 212, and second outer layer 214. Intermediate layer 208 is a patterned encapsulant layer defining perforations. Metal foil 210 is embossed through the perforations in intermediate layer 208. Intermediate layer 208 also includes a layer of adhesive between embossed regions of metal foil 210 and electrically conductive protrusions 216 on photovoltaic cells 206 to which the embossed metal foil 210 connects. The adhesive may be a liquid at room temperature that cures at lamination temperatures (130° C.-160° C.), and it may be applied to either the embossed regions of metal foil 210 or electrically conductive protrusions 216 on photovoltaic cells 206. The adhesive may be applied to metal foil 210 or to photovoltaic cells 206 by any suitable means, such as screen printing and jet dispensing. The adhesive may be any material that is capable of bonding to metal foil 210 and electrically conductive protrusions 216 of photovoltaic cells 206.

Suitable adhesives are typically electrical insulators, and are typically thin enough in at least some regions so that direct electrical communication (e.g., low-resistance electrical conduction) may occur between electrically conductive protrusions 216 of photovoltaic cells 206 and metal foil 210. In some cases, there is direct contact between electrically conductive protrusions 216 and metal foil 210. The adhesive may be, for example, epoxy, acrylate, or silicone, or any other suitable material. The surface morphology of metal foil 210 may be modified by chemical or physical abrasion or by the application of particles (e.g., by sintering), in a pattern or over the entire surface, to create a porous surface region that promotes bonding of the adhesive layer.

After the adhesive is applied to the desired areas and photovoltaic cells 206 are positioned on intermediate layer 208, first encapsulant 204 and first outer layer 202 may be stacked on photovoltaic cells 206. The stack of materials may then be heated and pressurized to form a laminate. Alternatively, any other suitable process may be used to remove air bubbles from photovoltaic module 200, melt and cross-link or cure the encapsulant or adhesive layers, and bring the embossed areas of metal foil 210 into more intimate contact with electrically conductive protrusions 216 of photovoltaic cells 206.

Photovoltaic module 200 may include an edge seal around at least one edge of the module, a frame attached around at least one edge of the module, mounting rails attached proximate the second outer layer of the module, a junction box attached to the second outer layer, or any combination thereof.

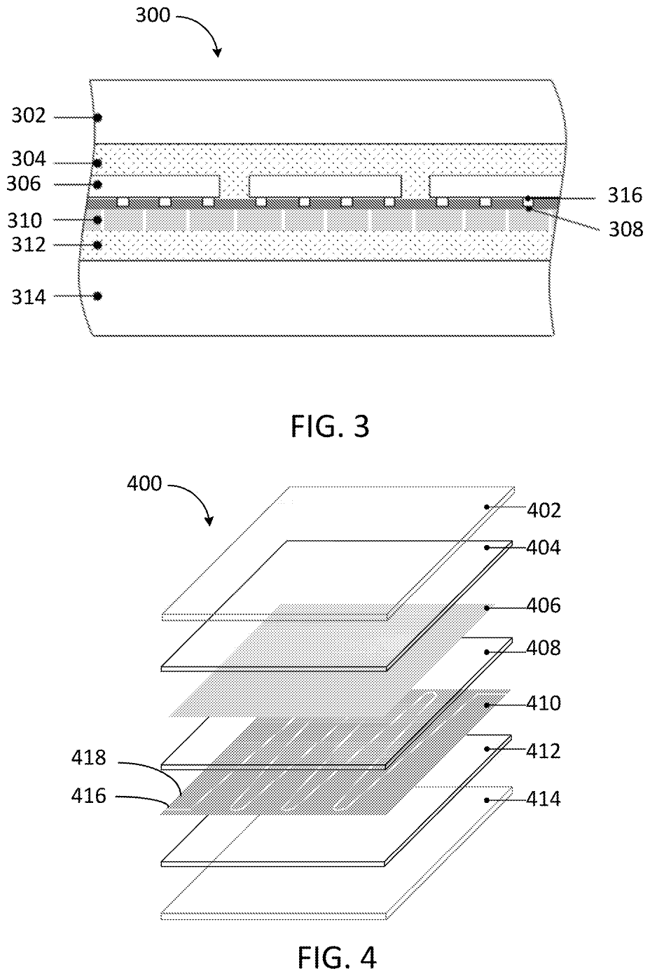

FIG. 3 is a cross-sectional view of photovoltaic module 300. Photovoltaic module 300 has first outer layer 302, first encapsulant 304, photovoltaic cells 306, intermediate layer 308, metal foil 310, second encapsulant 312, and second outer layer 314. Intermediate 308 includes a layer of adhesive. Metal foil 310 is planar (i.e., not embossed.) Photovoltaic cells 306 include a dielectric layer that covers regions of a given polarity not intended to make direct or electrical connection to metal foil 310. The adhesive may be a liquid at room temperature that cures at lamination temperatures (130° C.-160° C.), and it may be applied to metal foil 310 or a second side of the photovoltaic cells 306, covering some or all of the surface to which it is applied. The adhesive may be applied, for example, by screen printing, blade coating, jet dispensing, or any other suitable method. The adhesive may be any material that is capable of bonding to metal foil 310 and electrically conductive protrusions 316 of photovoltaic cells 306.

Suitable adhesives are typically insulators, but the adhesive layer can be thin enough in at least some regions so that low-resistance electrical conduction (direct electrical communication) may occur between electrically conductive protrusions 316 of photovoltaic cells 306 and metal foil 310. The adhesive may be, for example, epoxy, acrylate, or silicone, or any other suitable material. The surface morphology of metal foil 310 may be modified by chemical or physical abrasion or by the application of particles (by sintering, for example), either in a pattern or over the surface, to create a porous surface region that promotes bonding of the adhesive layer.

After the adhesive is applied and photovoltaic cells 306 are positioned on intermediate layer 308, first encapsulant 304 and first outer layer 302 may be stacked on top of photovoltaic cells 306. The stack of materials may then be heated and pressurized to form a laminate. Alternatively, any other suitable process may be used to remove air bubbles from photovoltaic module 300, melt and cross-link or cure the encapsulant or adhesive layers, and bring metal foil 310 into more intimate contact with electrically conductive protrusions 316 of photovoltaic cells 306.

After lamination, if second outer layer 314 of photovoltaic module 300 is optically transparent, a robust electrical connection between the electrical contacts of the metal foil and the electrically conductive protrusions of the photovoltaic cells may be optionally formed using a laser to weld the two metals together through the transparent second outer layer of the module. The laser may have any wavelength that is not appreciably absorbed by second outer layer 314 and second encapsulant 312. Examples of suitable lasers include a millisecond Nd:YAG laser that can deliver 30 mJ-150 mJ per pulse, a fiber optic laser running at frequencies between 10 kHZ and 4 MHz, or any other laser that enables the metal of the electrical contact to alloy with the metal on the cell.

FIG. 4 is an exploded view of a portion of photovoltaic module 400. Photovoltaic module 400 includes first outer layer 402, first encapsulant 404, back-contact photovoltaic cells 406, intermediate layer 408, metal foil 410, second encapsulant 412, and second outer layer 414. Metal foil 410 is separated along opening 416 into electrically isolated electrical contacts 418. FIG. 4 depicts the portion of photovoltaic module 400 during lay-up, prior to lamination. After lamination, the encapsulant is compressed and adheres adjacent layers together.

FIG. 5 is an exploded, cut-away view of a portion of photovoltaic module 500 with back-contact photovoltaic cell 506, intermediate layer 508, and metal foil 510. Metal foil 510 is separated along opening 516 into electrical isolated planar electrical contacts 518. Embossed portions 520 extend from electrical contacts 518. Intermediate layer 508 include perforations or openings 522 configured to allow embossed portions 520 to form direct electrical communication (e.g., direct contact) with electrically conductive protrusions extending from photovoltaic cell 506.

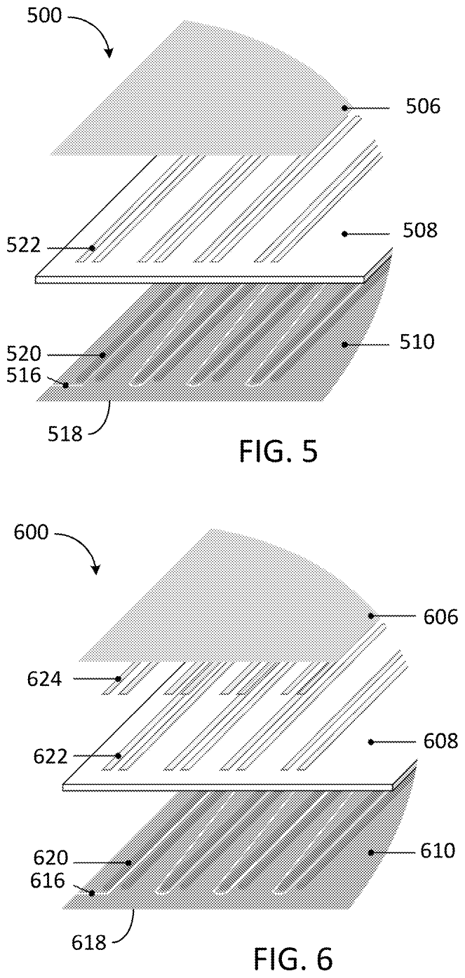

FIG. 6 is an exploded, cut-away view of a portion of photovoltaic module 600 with back-contact photovoltaic cell 606, intermediate layer 608, and metal foil 610. Metal foil 610 is separated along opening 616 into electrical isolated planar electrical contacts 618. Embossed portions 620 extend from electrical contacts 618. Intermediate layer 608 include perforations or openings 622 configured to allow embossed portions 620 to form direct electrical communication with electrically conductive protrusions extending from photovoltaic cell 506 through non-electrically conductive adhesive 624.

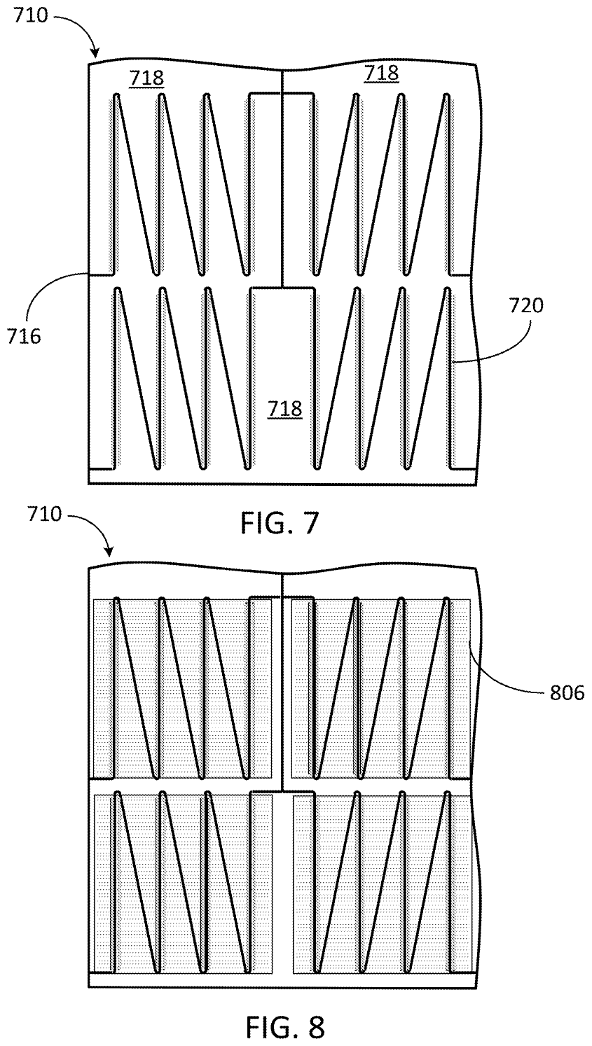

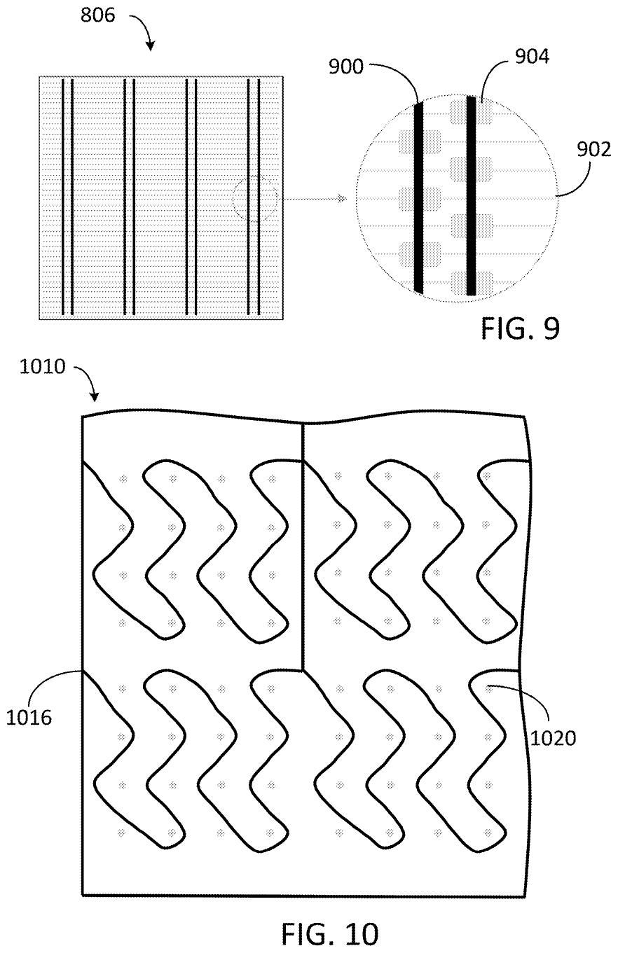

FIG. 7 is a top view of metal foil 710 having a first arrangement of openings 716, electrical contacts 718, and embossed portions 720. FIG. 8 is a top view of metal foil 710 of FIG. 7 aligned with and connected to four photovoltaic cells 806. FIG. 9 is a top view of photovoltaic cell 806 of FIG. 8. The enlarged portion shows busbars 900, fingers 902, and dielectric regions 904.

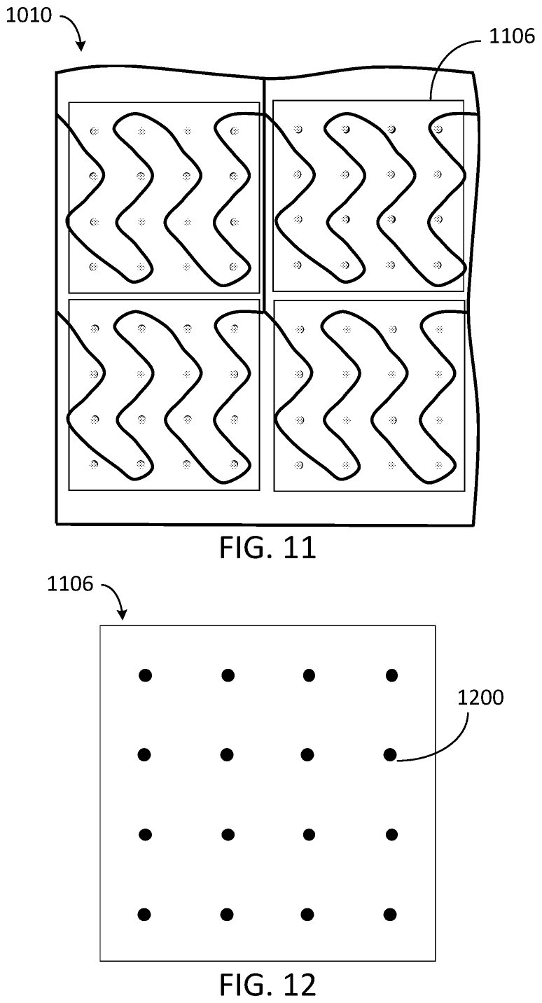

FIG. 10 is a top view of metal foil 1010 having a second arrangement of openings 1016 and embossed portions 1020. FIG. 11 is a top view of metal foil 1010 of FIG. 10 aligned with and connected to four photovoltaic cells 1106. FIG. 12 is a top view of photovoltaic cell 1106 of FIG. 11 showing electrically conductive protrusions 1200.

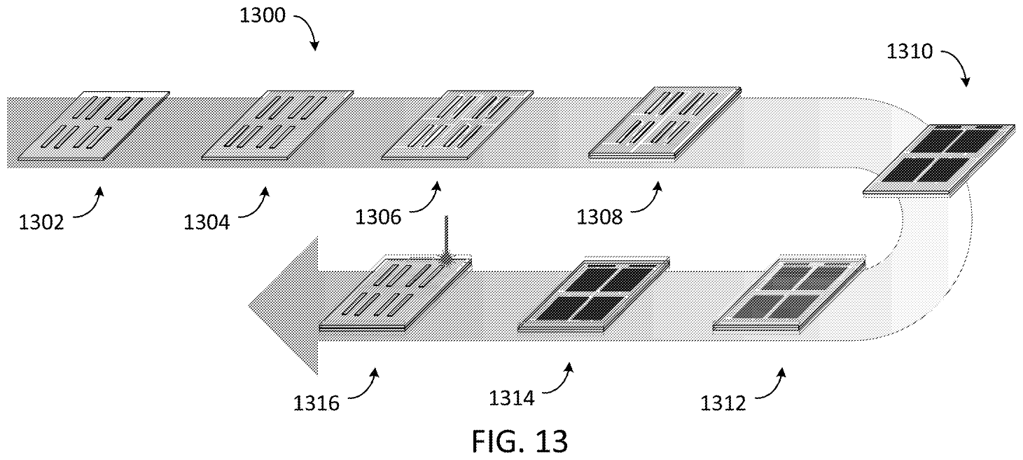

FIG. 13 depicts operations in a fabrication sequence for a photovoltaic module. In 1302, perforations are formed in an intermediate (encapsulant) layer. In 1304, metal foil is embossed through the encapsulant layer, and the metal foil and encapsulant layer are coupled (e.g., adhered). In 1306, the metal foil is separated to form electrical contacts, each electrical contact being electrically isolated from the other electrical contacts. In 1308, a second encapsulant and a second outer layer are superimposed on the metal foil and the intermediate layer. In 1310, photovoltaic cells are positioned on the intermediated layer. The bussing ribbon is threaded through the foil, the second encapsulant, and openings in the second outer layer. In 1312, the first encapsulant layer and the first outer layer are superimposed on the photovoltaic cells. In 1314, the assembly (or stack) formed in 1312 is laminated. In 1314, direct electrical communication is achieved between the electrically conductive protrusions of the photovoltaic cells and the metal foil by laser welding. Additional operations include edge trimming the laminate, framing the trimmed laminate, and applying sealing. A junction box is coupled to the photovoltaic module, and the photovoltaic module may be tested.

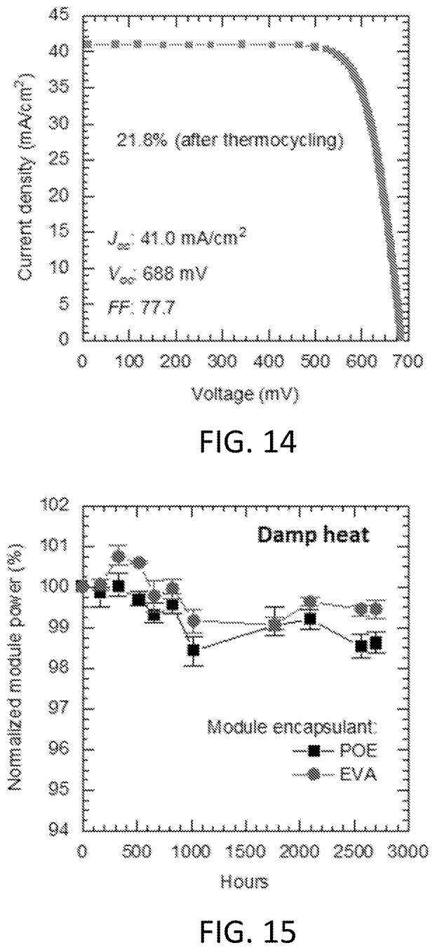

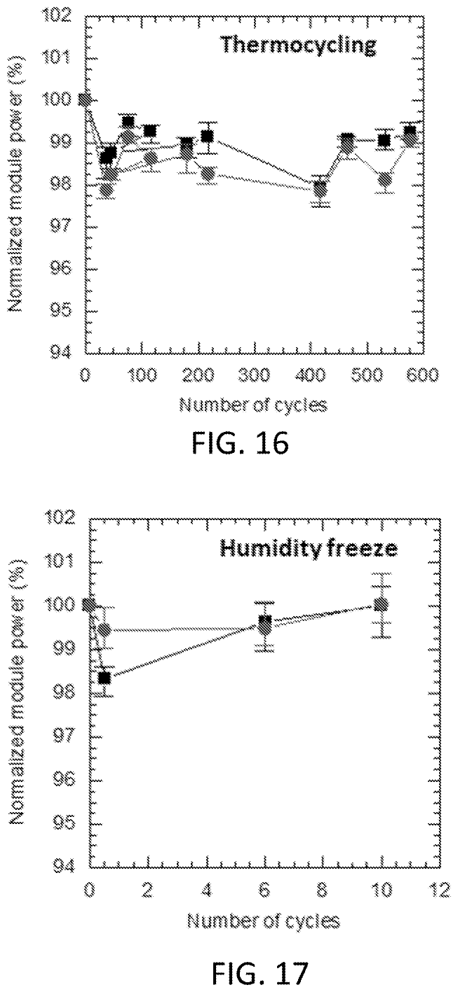

FIG. 14 shows current density-voltage characteristics of a photovoltaic module. FIG. 15 shows the relative performance of a photovoltaic module as a function of hours of damp-heat exposure. FIG. 16 shows the relative performance of a photovoltaic module as a function of numbers of thermocycles. FIG. 17 shows is the relative performance of a photovoltaic module as a function of numbers of humidity-freeze cycles.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A photovoltaic module comprising:
a metal foil defining a multiplicity of electrical contacts, each electrical contact electrically isolated from the other electrical contacts; and
a plurality of back-contact photovoltaic cells superimposed over the metal foil and electrically connected via the multiplicity of electrical contacts, each photovoltaic cell comprising:
a first side configured to absorb light; and
a second side comprising a first electrically conductive protrusion and a second electrically conductive protrusion,
wherein the first electrically conductive protrusion of a first one of the photovoltaic cells is in direct electrical communication with a first one of the multiplicity of electrical contacts, and the second electrically conductive protrusion of the first one of the photovoltaic cells is in direct electrical communication with a second one of the electrical contacts.

2. The photovoltaic module of claim 1, wherein the multiplicity of electrical contacts comprises pairs of adjacent electrical contacts, each pair of adjacent electrical contacts separated by an opening through the metal foil.

3. The photovoltaic module of claim 1, wherein the first electrically conductive protrusion of the first one of the photovoltaic cells is laser welded to the first one of the multiplicity of electrical contacts.

4. The photovoltaic module of claim 1, wherein the first electrically conductive protrusion of the first one of the photovoltaic cells is adhered to the first one of the multiplicity of electrical contacts with a non-electrically conductive adhesive.

5. The photovoltaic module of claim 1, wherein each of the multiplicity of electrical contacts is embossed such that an embossed portion of each of the multiplicity of electrical contacts extends from a plane of the metal foil toward the plurality of photovoltaic cells.

6. The photovoltaic module of claim 1, wherein each embossed portion extends from the plane of the metal foil by a distance between 10 μm and 800 μm.

7. The photovoltaic module of claim 1, wherein the first electrically conductive protrusion of a first one of the photovoltaic cells is in direct electrical communication with the embossed portion of the first one of the multiplicity of electrical contacts, and the second electrically conductive protrusion of the first one of the photovoltaic cells is in direct electrical communication with the embossed portion of the second one of the electrical contacts.

8. The photovoltaic module of claim 1, further comprising an encapsulant layer between the metal foil and the plurality of photovoltaic cells.

9. The photovoltaic module of claim 8, wherein each of the multiplicity of electrical contacts is embossed such that an embossed portion of each of the multiplicity of electrical contacts extends from a plane of the metal foil and through an opening in the encapsulant layer toward the plurality of photovoltaic cells.

10. The photovoltaic module of claim 9, wherein a thickness of the encapsulant layer and the distance each embossed portion extends from the plane of the metal foil are substantially the same.

11. The photovoltaic module of claim 1, further comprising a first outer layer and a second outer layer, wherein the metal foil and the plurality of photovoltaic cells are positioned between the first outer layer and the second outer layer.

12. The photovoltaic module of claim 1, further comprising a first encapsulant layer between the first outer layer and the plurality of photovoltaic cells and a second encapsulant layer between the metal foil and the second outer layer.

13. A method of fabricating a photovoltaic module, the method comprising:
separating a metal foil into a plurality of electrical contacts, wherein each electrical contact is electrically isolated from each of the other electrical contacts;
superimposing a plurality of photovoltaic cells over the plurality of electrical contacts, each photovoltaic cell comprising a first electrically conductive protrusion and a second electrically conductive protrusion; and
forming a direct electrical coupling between the first electrically conductive protrusion of a first one of the photovoltaic cells and a first one of the electrical contacts and between the second electrically conductive protrusion of the first one of the photovoltaic cells and a second one of the electrical contacts.

14. The method of claim 13, wherein separating the metal foil comprises removing a portion of the metal foil.

15. The method of claim 14, wherein removing the portion of the metal foil comprises laser ablating or mechanically milling the portion of the metal foil.

16. The method of claim 13, further comprising embossing the metal foil before separating the metal foil into the plurality of electrical contacts.

17. The method of claim 16, wherein embossing the metal foil yields an embossed portion of the each of the multiplicity of electrical contacts extending from a plane of the metal foil.

18. The method of claim 17, further comprising:
forming openings in an intermediate layer before embossing the metal foil;
superimposing the metal foil and the intermediate layer; and
embossing the metal foil through the openings in the intermediate layer.

19. The method of claim 16, further comprising laser welding the first electrically conductive protrusion of the first one of the photovoltaic cells to the first one of the electrical contacts.

20. The method of claim 13, wherein forming the direct electrical coupling between the first electrically conductive protrusion of the first one of the photovoltaic cells and the first one of the electrical contacts comprises adhering the first electrically conductive protrusion of the first one of the photovoltaic cells and the first one of the electrical contacts with an non-electrically conductive adhesive.
